(19) United States
(12) Patent Application Publication
(10) Pub. No.: US 2025/0354045 A1
(43) Pub. Date: Nov. 20, 2025

(54) COOLING LIQUID AND COOLING SYSTEM

(71) Applicant: INDUSTRIAL TECHNOLOGY RESEARCH INSTITUTE, Hsinchu (TW)

(72) Inventors: Chen-Kuang CHIANG, Taichung City (TW); Hsiang-Yen TSAO, Zhubei City (TW); Jyh-Long JENG, New Taipei City (TW); Hao-Chien LEE, Taipei City (TW)

(73) Assignee: INDUSTRIAL TECHNOLOGY RESEARCH INSTITUTE, Hsinchu (TW)

(21) Appl. No.: 19/212,246

(22) Filed: May 19, 2025

Related U.S. Application Data
(60) Provisional application No. 63/649,534, filed on May 20, 2024.

(30) Foreign Application Priority Data
May 19, 2025 (TW) 114118631

(51) Int. Cl. C09K 5/10; H05K 7/20

(52) U.S. Cl. CPC C09K 5/10; H05K 7/20236

(57) ABSTRACT

A cooling liquid includes 100 parts by weight of a dielectric compound having a chemical structure of

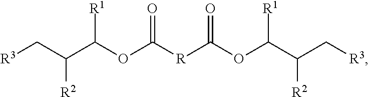

wherein R is C₂₋₁₆ alkylene group, R¹ is H or C₁₋₃ alkyl group, R² is H or C₁₋₃ alkyl group, and at least one of R¹ and R² is C₁₋₃ alkyl group, and R³ is H or C₁₋₇ alkyl group; 0.01 to 0.5 parts by weight of an antioxidant having a chemical structure of

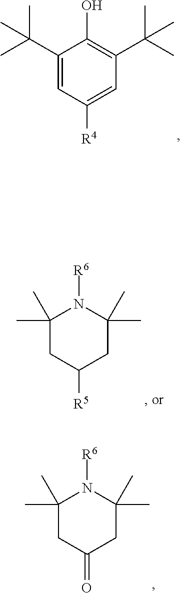

wherein R⁴ is H or C₁₋₆ alkyl group; R⁵ is H, C₁₋₆ alkyl group, acrylate group, or methacrylate group; and R⁶ is H or methyl group; and 0.0001 to 0.01 parts by weight of a triazole-based compound or a diimidazole-based compound.

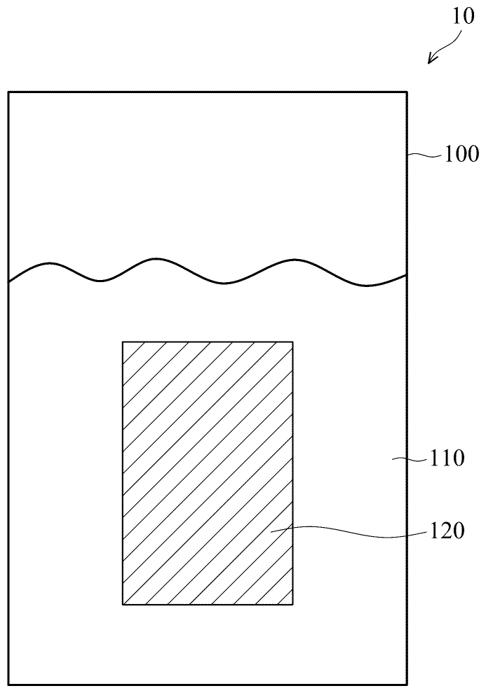

### CROSS REFERENCE TO RELATED APPLICATIONS

This application claims the benefit of U.S. Provisional Application No. 63/649,534, filed on May 20, 2024.

The present application is based on, and claims priority from, Taiwan Application Serial Number 114118631, filed on May 19, 2025, the disclosure of which is hereby incorporated by reference herein in its entirety.

### TECHNICAL FIELD

The technical field relates to a cooling liquid and a cooling system.

### BACKGROUND

Electronic components generate heat during operation, causing devices to heat up rapidly, and an efficient heat dissipation technology is required to keep the stable operation of a system. Otherwise, the performance of the device will be limited. Different heat dissipation technologies have varying energy efficiency. As ESG (Environmental, Social, Governance) concepts become widespread, heat dissipation technology should adapt to current demands for green technology. Among various heat dissipation technologies, immersion cooling is the most effective way to save energy and quickly cool.

In general, cooling liquids not only require low viscosity but also need to overcome material aging issues to prevent system failures due to increased viscosity and acid value.

### SUMMARY

One embodiment of the disclosure provides a cooling liquid, including: 100 parts by weight of a dielectric compound having a chemical structure of

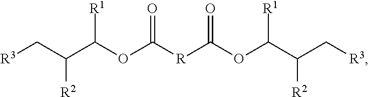

wherein R is C₂₋₁₆ alkylene group, R¹ is H or C₁₋₃ alkyl group, R² is H or C₁₋₃ alkyl group, and at least one of R¹ and R² is C₁₋₃ alkyl group, and R³ is H or C₁₋₇ alkyl group; 0.01 to 0.5 parts by weight of an antioxidant having a chemical structure of

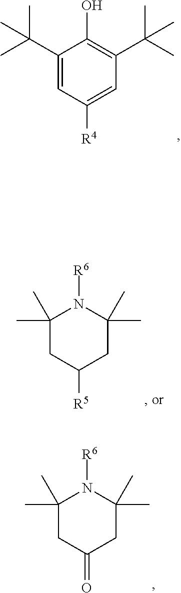

wherein R⁴ is H or C₁₋₆ alkyl group; R⁵ is H, C₁₋₆ alkyl group, acrylate group, or methacrylate group; and R⁶ is H or methyl group; and 0.0001 to 0.01 parts by weight of a triazole-based compound or a diimidazole-based compound.

One embodiment of the disclosure provides a cooling system, including a container; the described cooling liquid disposed in the container; and an electronic device at least partially immersed in the cooling liquid.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

Figure shows a cooling system in one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

One embodiment of the disclosure provides a cooling liquid, including: 100 parts by weight of a dielectric compound having a chemical structure of

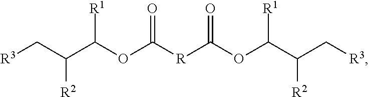

wherein R is C₂₋₁₆ alkylene group, R¹ is H or C₁₋₃ alkyl group, R² is H or C₁₋₃ alkyl group, and at least one of R¹ and R² is C₁₋₃ alkyl group, and R³ is H or C₁₋₇ alkyl group. In some embodiments, the dielectric compound is formed by reacting a C₄₋₁₈ linear diacid (HOOC—R—COOH) and a C₄₋₁₁-branched alcohol

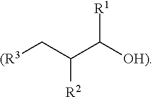

The structural feature of the branched alcohol is that at least one of the α or β position to the hydroxyl group is substituted with a C₁₋₃ alkyl group. Therefore, the dielectric compound of the disclosure has a C₁₋₃ branched chain on the α or β carbon to the ester group. If both R¹ and R² are H, the kinematic viscosity and acid value of the dielectric compound may be too high to be applied in the cooling liquid. For example, the linear diacid is succinic acid, adipic acid, suberic acid, sebacic acid, dodecanedioic acid, tetradecanedioic acid, hexadecanedioic acid, or octadecanedioic acid. For example, the branched alcohol is 2-ethyl-1-butanol, isobutyl alcohol, 2-ethylhexanol, 2-ethyloctanol, 2-ethylnonanol, 2-methylbutanol, 2-methylhexanol, 2,4-diethylheptanol, 2-heptanol, or 2-nonanol. In some embodiments, the dielectric compound has a chemical structure of

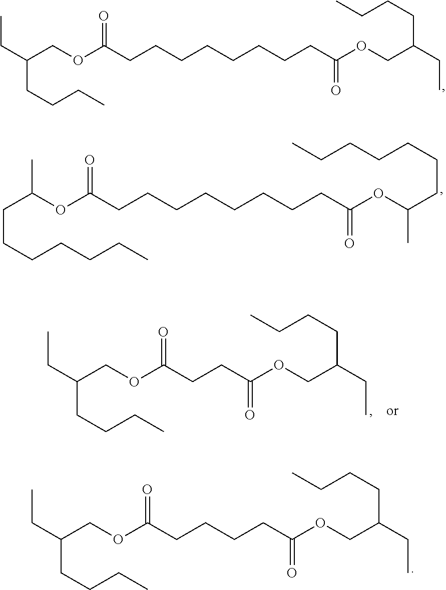 [SMILES: CCCCC(CC)COC(=O)CCCCCCCCC(=O)OCC(CC)CCCC ; CCCCCCCC(C)OC(=O)CCCCCCCCC(=O)OC(C)CCCCCCC ; CCCCC(CC)COC(=O)CCC(=O)OCC(CC)CCCC ; CCCCC(CC)COC(=O)CCCCC(=O)OCC(CC)CCCC]

In some embodiments, the dielectric compound has a kinematic viscosity of 5 cst to 15 cst at 40° C.

In some embodiments, the cooling liquid further includes 0.01 to 0.5 parts by weight of an antioxidant on the basis of 100 parts by weight of the dielectric compound. If the amount of the antioxidant is too high, the kinematic viscosity of the cooling liquid after long-term use may be increased to degrade the cooling effect. If the amount of the antioxidant is too low, the acid value of the cooling liquid after long-term use may be increased to degrade the cooling effect. The antioxidant has a chemical structure of

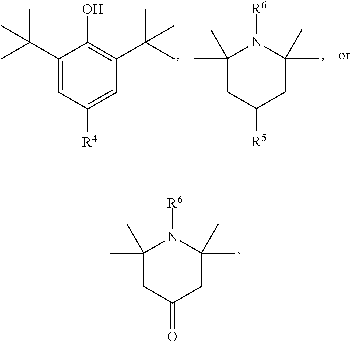

wherein R⁴ is H or C₁₋₆ alkyl group; R⁵ is H, C₁₋₆ alkyl group, acrylate group, or methacrylate group; and R⁶ is H or methyl group. In the chemical structure of the antioxidant, all ortho positions to the hydroxyl group (or all α positions to the amine group) are substituted with high steric hindrance groups. If not all of the ortho positions are substituted by the high steric hindrance groups (or even unsubstituted), the cooling liquid may generate precipitation after long-term use to degrade the cooling effect. For example, the antioxidant can be 2,6-di-tert-butyl-p-cresol, 2,6-di-tert-butyl-4-ethylphenol, 2,6-di-tert-butyl-4-sec-butylphenol, 2,6-di-tert-butyl-4-butylphenol, 1,2,2,6,6-pentamethyl-4-piperidyl methacrylate, 1,2,2,6,6-pentamethylpiperidine, 2,2,6,6-tetramethylpiperidine, 2,2,6,6-tetramethyl-4-piperidinyl methacrylate, or 2,2,6,6-tetramethylpiperidone.

In some embodiments, the cooling liquid further includes 0.0001 to 0.01 parts by weight of a triazole-based compound or a diimidazole-based compound on the basis of 100 parts by weight of the dielectric compound. If the amount of the triazole-based compound or the diimidazole-based compound is overly high, the cooling liquid may generate precipitation after long-term use to degrade the cooling effect. If the amount of the triazole-based compound or the diimidazole-based compound is overly low, it may quickly consume the antioxidant in the cooling liquid. Therefore, the acid value of the cooling liquid may be increased after long-term use to degrade the cooling effect. For example, the triazole-based compound is 3-salicylamido-1,2,4-triazole, methylbenzotriazole, 5-methylbenzotriazole, 5-carboxybenzotriazole, or 1-hydroxybenzotriazole. For example, the diimidazole-based compound is 2-phenylimidazole, 5-aminobenzimidazole, or 4-(imidazol-1-yl) aniline.

In some embodiments, the cooling liquid is essentially consisting of the described dielectric compound, the antioxidant, and the triazole-based compound or the diimidazole-based compound, with the absence of other common content in the cooling liquid. For example, the cooling liquid in some embodiments is free of vegetable oil, animal oil, mineral oil, or a combination thereof. In some embodiments, the cooling liquid is also free of any general additive such as inorganic powder, pigment, leveling agent, surfactant, or the like. In some embodiments, if the cooling liquid contains another oil or additive, the properties and the cooling effect of the cooling liquid may be possibly degraded.

As shown in Figure, one embodiment of the disclosure provides a cooling system 10, including a container 100, the cooling liquid 110 disposed in the container 100; and an electronic device 120 at least partially immersed in the cooling liquid 110. The electronic device 120 can be completely immersed in the cooling liquid 110 as shown in Figure, but is not limited thereto. For example, the electronic device 120 can be partially immersed in the cooling liquid 110 and partially exposed. The container 100 can be connected to an external cooling device (not shown) through a pipe (not shown), thereby transferring the cooling liquid of a higher temperature to the external cooling device and transferring back the cooling liquid of a lower temperature to the container 100. As such, it may achieve the effect of cooling the electronic device 120. The above description is only one possible manner of the cooling system 10. One skilled in the art may apply the cooling liquid in any reasonable manner without being limited to the above manner.

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

### Synthesis Example 1

100 g of sebacic acid and 91.4 g of 2-ethylhexanol were mixed, and nitrogen was then introduced to remove moisture for 30 minutes. Subsequently, 0.095 g of butyl titanate serving as a catalyst was added to the mixture, which was heated to 180° C. and continuously stirred to react for 4 hours to obtain a crude product. The crude product was heated to 150° C. under a pressure of 20 torr and fractionally distilled for removing water and excess reactants to obtain an initially purified product. Because a little organic acid remained in the initially purified product, celite and the initially purified product (w/w=15/100) were heated to 60° C. and continuously stirred and mixed. The mixture was then filtered to obtain a dielectric compound to measure its kinematic viscosity (measured according to the standard ASTM D7042) and acid value (measured according to the standard ASTM D664). The dielectric compound had a chemical structure of

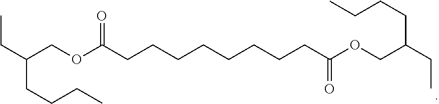 [SMILES: CCCCC(CC)COC(=O)CCCCCCCCC(=O)OCC(CC)CCCC]

The dielectric compound had a molecular weight of 426, a kinematic viscosity of 19 cst at 25° C., a kinematic viscosity of 11 cst at 40° C., a kinematic viscosity of 2.8 cst at 100° C., and an acid value after purification of 0.01 mg KOH/g.

### Synthesis Example 2

Synthesis Example 2 was similar to Synthesis Example 1, and the difference in Synthesis Example 2 was 2-ethylhexanol being replaced with 101.2 g of 2-nonanol. The dielectric compound had a chemical structure of

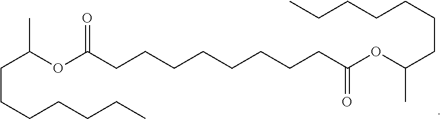 [SMILES: CCCCCCCC(C)OC(=O)CCCCCCCCC(=O)OC(C)CCCCCCC]

The dielectric compound had a molecular weight of 454, a kinematic viscosity of 24 cst at 25° C., a kinematic viscosity of 13 cst at 40° C., a kinematic viscosity of 2.9 cst at 100° C., and an acid value after purification of 0.01 mg KOH/g.

### Synthesis Example 3

Synthesis Example 3 was similar to Synthesis Example 1, and the difference in Synthesis Example 3 was sebacic acid being replaced with 58.2 g of succinic acid. The dielectric compound had a chemical structure of

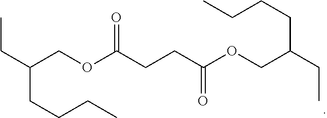 [SMILES: CCCCC(CC)COC(=O)CCC(=O)OCC(CC)CCCC]

The dielectric compound had a molecular weight of 342, a kinematic viscosity of 8 cst at 25° C., a kinematic viscosity of 5 cst at 40° C., a kinematic viscosity of 1.5 cst at 100° C., and an acid value after purification of 0.01 mg KOH/g.

### Synthesis Example 4

Synthesis Example 4 was similar to Synthesis Example 1, and the difference in Synthesis Example 4 was sebacic acid being replaced with 72.2 g of adipic acid. The dielectric compound had a chemical structure of

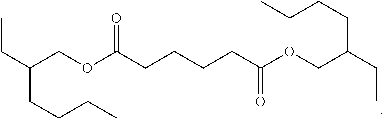 [SMILES: CCCCC(CC)COC(=O)CCCCC(=O)OCC(CC)CCCC]

The dielectric compound had a molecular weight of 370, a kinematic viscosity of 10 cst at 25° C., a kinematic viscosity of 7 cst at 40° C., a kinematic viscosity of 2.0 cst at 100° C., and an acid value after purification of 0.01 mg KOH/g.

### Comparative Synthesis Example 1

Comparative Synthesis Example 1 was similar to Synthesis Example 1, and the difference in Comparative Synthesis Example 1 was 2-ethylhexanol being replaced with 101.2 g of 3-ethylheptanol. The dielectric compound had a chemical structure of

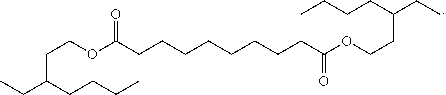 [SMILES: CCCCC(CC)CCOC(=O)CCCCCCCCC(=O)OCCC(CC)CCCC]

The dielectric compound had a molecular weight of 454, a kinematic viscosity of 26 cst at 25° C., a kinematic viscosity of 15 cst at 40° C., a kinematic viscosity of 3.0 cst at 100° C., and an acid value after purification of 0.56 mg KOH/g.

### Comparative Synthesis Example 2

Comparative Synthesis Example 2 was similar to Synthesis Example 1, and the difference in Comparative Synthesis Example 2 was 2-ethylhexanol being replaced with 111.1 g of 3,7-dimethyloctanol. The dielectric compound had a chemical structure of

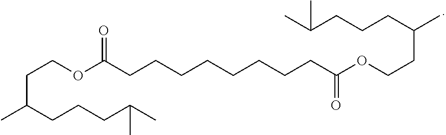 [SMILES: CC(C)CCCC(C)CCOC(=O)CCCCCCCCC(=O)OCCC(C)CCCC(C)C]

The dielectric compound had a molecular weight of 482, a kinematic viscosity of 34 cst at 25° C., a kinematic viscosity of 20 cst at 40° C., a kinematic viscosity of 3.8 cst at 100° C., and an acid value after purification of 0.72 mg KOH/g.

### Comparative Synthesis Example 3

Comparative Synthesis Example 3 was similar to Synthesis Example 1, and the difference in Comparative Synthesis Example 3 was 2-ethylhexanol being replaced with 101.2 g of 4,6-dimethyloctanol.

The dielectric compound had a chemical structure of

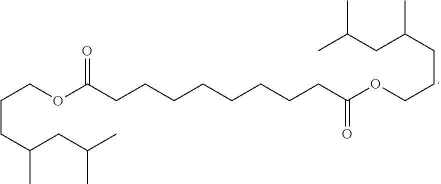 [SMILES: CC(C)CC(C)CCCOC(=O)CCCCCCCCC(=O)OCCCC(C)CC(C)C]

The dielectric compound had a molecular weight of 454, a kinematic viscosity of 28 cst at 25° C., a kinematic viscosity of 16 cst at 40° C., a kinematic viscosity of 3.6 cst at 100° C., and an acid value after purification of 0.77 mg KOH/g.

### Comparative Synthesis Example 4

Comparative Synthesis Example 4 was similar to Synthesis Example 1, and the difference in Comparative Synthesis Example 4 was 2-ethylhexanol being replaced with 91.4 g of octanol. The dielectric compound had a chemical structure of

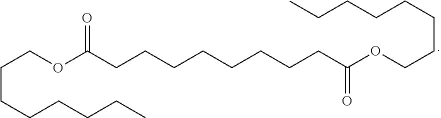 [SMILES: CCCCCCCCOC(=O)CCCCCCCCC(=O)OCCCCCCCC]

The dielectric compound had a molecular weight of 426, a kinematic viscosity of 18 cst at 25° C., a kinematic viscosity of 11 cst at 40° C., a kinematic viscosity of 2.8 cst at 100° C., and an acid value after purification of 0.84 mg KOH/g.

### Comparative Synthesis Example 5

Comparative Synthesis Example 5 was similar to Synthesis Example 1, and the difference in Comparative Synthesis Example 5 was 2-ethylhexanol being replaced with 101.2 g of nonanol. The dielectric compound had a chemical structure of

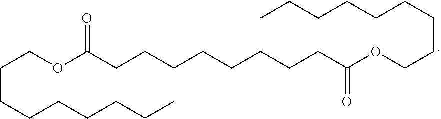 [SMILES: CCCCCCCCCOC(=O)CCCCCCCCC(=O)OCCCCCCCCC]

The dielectric compound had a molecular weight of 454, a kinematic viscosity of 29 cst at 25° C., a kinematic viscosity of 16 cst at 40° C., a kinematic viscosity of 3.6 cst at 100° C., and an acid value after purification of 0.88 mg KOH/g.

Accordingly, the dielectric compound formed by reacting the branched alcohol (having C₁₋₃ alkyl substituents at a or β position of the hydroxyl group) and the linear diacid had a lower kinematic viscosity and a lower acid value.

### Example 1

100 parts by weight of the dielectric compound in Synthesis Example 1, 0.5 parts by weight of 2,6-di-tert-butyl-p-cresol (butylated hydroxytoluene, BHT) serving as an antioxidant, and 0.001 parts by weight of 3-salicylamido-1,2,4-triazole were mixed to form a cooling liquid. BHT had a chemical structure of

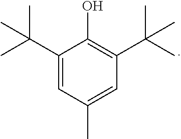 [SMILES: Cc1cc(C(C)(C)C)c(O)c(C(C)(C)C)c1]

The accelerated aging test of the cooling liquid was performed according to the standard ASTM D1934, as described below. Immersed a 45 cm² copper foil into 900 mL of the cooling liquid, which was exposed to atmosphere at 115° C. and stirred at a high speed (200 rpm) for 96 hours. Thereafter, the kinematic viscosity and the acid value of the cooling liquid were measured. The cooling liquid had an initial kinematic viscosity of 19 cst at 25° C., and a kinematic viscosity after aging of 22 cst at 25° C. The cooling liquid had an initial acid value of 0.01 mg KOH/g, and an acid value after aging of 0.01 mg KOH/g.

### Example 2

Example 2 was similar to Example 1, and the difference in Example 2 was BHT being replaced with 1,2,2,6,6-pentamethyl-4-piperidyl methacrylate (ANSORB-28, commercially available from Anchem Technology Corporation). ANSORB-28 had a chemical structure of

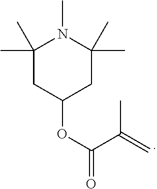 [SMILES: C=C(C)C(=O)OC1CC(C)(C)N(C)C(C)(C)C1]

The cooling liquid had an initial kinematic viscosity of 19 cst at 25° C., and a kinematic viscosity after aging of 22 cst at 25° C. The cooling liquid had an initial acid value of 0.01 mg KOH/g, and an acid value after aging of 0.01 mg KOH/g.

### Example 3

Example 3 was similar to Example 1, and the difference in Example 3 was 0.5 parts by weight of BHT being decreased to 0.01 parts by weight of BHT. The cooling liquid had an initial kinematic viscosity of 19 cst at 25° C., and a kinematic viscosity after aging of 19 cst at 25° C. The cooling liquid had an initial acid value of 0.01 mg KOH/g, and an acid value after aging of 0.02 mg KOH/g.

### Example 4

Example 4 was similar to Example 1, and the difference in Example 4 was BHT being replaced with 2,6-di-tert-butyl-4-sec-butylphenol (commercially available from TCI Co., Ltd.). 2,6-di-tert-butyl-4-sec-butylphenol had a chemical structure of

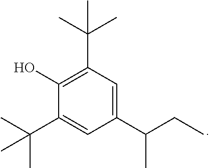 [SMILES: CCC(C)c1cc(C(C)(C)C)c(O)c(C(C)(C)C)c1]

The cooling liquid had an initial kinematic viscosity of 19 cst at 25° C., and a kinematic viscosity after aging of 24 cst at 25° C. The cooling liquid had an initial acid value of 0.01 mg KOH/g, and an acid value after aging of 0.01 mg KOH/g.

### Example 5

Example 5 was similar to Example 1, and the difference in Example 5 was BHT being replaced with 2,2,6,6-tetramethylpiperidine (commercially available from TCI Co., Ltd.). 2,2,6,6-tetramethylpiperidine had a chemical structure of

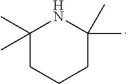

The cooling liquid had an initial kinematic viscosity of 19 cst at 25° C., and a kinematic viscosity after aging of 21 cst at 25° C. The cooling liquid had an initial acid value of 0.01 mg KOH/g, and an acid value after aging of 0.01 mg KOH/g.

### Comparative Example 1

Comparative Example 1 was similar to Example 1, and the difference in Comparative Example 1 was BHT being replaced with Lowinox®CA22 (commercially available from Easchem Co., Ltd.). Lowinox®CA22 had a chemical structure of

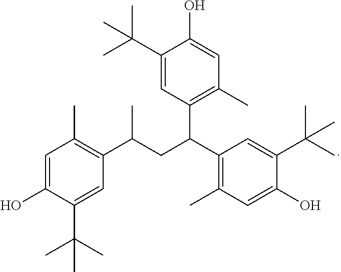 [SMILES: Cc1cc(O)c(C(C)(C)C)cc1C(C)CC(c1cc(C(C)(C)C)c(O)cc1C)c1cc(C(C)(C)C)c(O)cc1C]

The cooling liquid had an initial kinematic viscosity of 19 cst at 25° C., and generated gel precipitation after aging at 25° C. The cooling liquid had an initial acid value of 0.01 mg KOH/g, and an acid value after aging of 0.19 mg KOH/g.

### Comparative Example 2

Comparative Example 2 was similar to Example 1, and the difference in Comparative Example 2 was BHT being replaced with Naugawhite® (commercially available from Easchem Co., Ltd.). Naugawhite® had a chemical structure of

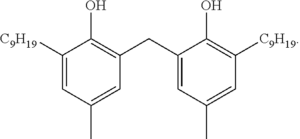

The cooling liquid had an initial kinematic viscosity of 19 cst at 25° C., and generated precipitation after aging at 25° C. The cooling liquid had an initial acid value of 0.01 mg KOH/g, and an acid value after aging of 0.22 mg KOH/g.

### Comparative Example 3

Comparative Example 3 was similar to Example 1, and the difference in Comparative Example 3 was 0.5 parts by weight of BHT being increased to 0.75 parts by weight of BHT. The cooling liquid had an initial kinematic viscosity of 19 cst at 25° C., and a kinematic viscosity after aging of 33 cst at 25° C. The cooling liquid had an initial acid value of 0.01 mg KOH/g, and an acid value after aging of 0.01 mg KOH/g.

### Comparative Example 4

Comparative Example 4 was similar to Example 1, and the difference in Comparative Example 4 was 0.5 parts by weight of BHT being decreased to 0.005 parts by weight of BHT. The cooling liquid had an initial kinematic viscosity of 19 cst at 25° C., and a kinematic viscosity after aging of 19 cst at 25° C. The cooling liquid had an initial acid value of 0.01 mg KOH/g, and an acid value after aging of 0.08 mg KOH/g.

Accordingly, too much or too little antioxidant would impact the kinematic viscosity and the acid value of the cooling liquid after aging. In addition, not all kinds of antioxidants were appropriate for use in the cooling liquid in the disclosure.

### Comparative Example 5

Comparative Example 5 was similar to Example 1, and the difference in Comparative Example 5 was BHT being replaced with Irganox® L 135 (commercially available from BASF Co., Ltd.). Irganox® L 135 had a chemical structure of

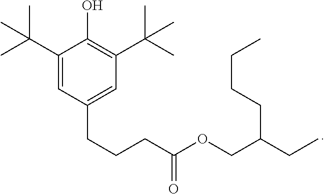 [SMILES: CCCCC(CC)COC(=O)CCCc1cc(C(C)(C)C)c(O)c(C(C)(C)C)c1]

The cooling liquid had an initial kinematic viscosity of 21 cst at 25° C., and a kinematic viscosity after aging of 34 cst at 25° C. The cooling liquid had an initial acid value of 0.01 mg KOH/g, and an acid value after aging of 0.11 mg KOH/g.

Accordingly, the carbon number of the antioxidant would impact the kinematic viscosity and the acid value of the cooling liquid after aging. Not all the antioxidants having the ortho position of the hydroxyl group (or the alpha position of the amine group) substituted with a high steric hindrance group were appropriate to serve as the content of the cooling liquid in the disclosure.

### Example 6

100 parts by weight of the dielectric compound in Synthesis Example 1, 0.05 parts by weight of BHT serving as an antioxidant, and 0.01 parts by weight of 3-salicylamido-1,2,4-triazole were mixed to form a cooling liquid. The accelerated aging test of the cooling liquid was performed according to the standard ASTM D1934. The cooling liquid had an initial kinematic viscosity of 19 cst at 25° C., and a kinematic viscosity after aging of 23 cst at 25° C. The cooling liquid had an initial acid value of 0.01 mg KOH/g, and an acid value after aging of 0.01 mg KOH/g. The antioxidant of the cooling agent had a half-life of 16 days (measured by HPLC-UV).

### Example 7

Example 7 was similar to Example 6, and the difference in Example 7 was 0.01 parts by weight of 3-salicylamido-1,2,4-triazole being decreased to 0.005 parts by weight of 3-salicylamido-1,2,4-triazole. The cooling liquid had an initial kinematic viscosity of 19 cst at 25° C., and a kinematic viscosity after aging of 20 cst at 25° C. The cooling liquid had an initial acid value of 0.01 mg KOH/g, and an acid value after aging of 0.01 mg KOH/g.

### Example 8

Example 8 was similar to Example 6, and the difference in Example 8 was 0.01 parts by weight of 3-salicylamido-1,2,4-triazole being decreased to 0.001 parts by weight of 3-salicylamido-1,2,4-triazole. The cooling liquid had an initial kinematic viscosity of 19 cst at 25° C., and a kinematic viscosity after aging of 19 cst at 25° C. The cooling liquid had an initial acid value of 0.01 mg KOH/g, and an acid value after aging of 0.01 mg KOH/g. The antioxidant of the cooling agent had a half-life of 14 days.

### Example 9

100 parts by weight of the dielectric compound in Synthesis Example 1, 0.05 parts by weight of BHT serving as an antioxidant, and 0.01 parts by weight of 2-phenylimidazole were mixed to form a cooling liquid. The accelerated aging test of the cooling liquid was performed according to the standard ASTM D1934. The cooling liquid had an initial kinematic viscosity of 19 cst at 25° C., and a kinematic viscosity after aging of 21 cst at 25° C. The cooling liquid had an initial acid value of 0.01 mg KOH/g, and an acid value after aging of 0.01 mg KOH/g. The antioxidant of the cooling agent had a half-life of 18 days.

### Example 10

100 parts by weight of the dielectric compound in Synthesis Example 1, 0.05 parts by weight of BHT serving as an antioxidant, and 0.001 parts by weight of 2-phenylimidazole were mixed to form a cooling liquid. The accelerated aging test of the cooling liquid was performed according to the standard ASTM D1934. The cooling liquid had an initial kinematic viscosity of 19 cst at 25° C., and a kinematic viscosity after aging of 19 cst at 25° C. The cooling liquid had an initial acid value of 0.01 mg KOH/g, and an acid value after aging of 0.01 mg KOH/g. The antioxidant of the cooling agent had a half-life of 14 days.

### Comparative Example 6

Comparative Example 6 was similar to Example 6, and the difference in Comparative Example 6 was 0.01 parts by weight of 3-salicylamido-1,2,4-triazole being increased to 0.02 parts by weight of 3-salicylamido-1,2,4-triazole. The cooling liquid had an initial kinematic viscosity of 19 cst at 25° C., and generated precipitation after aging at 25° C. The cooling liquid had an initial acid value of 0.01 mg KOH/g.

### Comparative Example 7

Comparative Example 7 was similar to Example 6, and the difference in Comparative Example 7 was free of 3-salicylamido-1,2,4-triazole (no triazole-based compound or diimidazole-based compound was added). The cooling liquid had an initial kinematic viscosity of 19 cst at 25° C., and a kinematic viscosity after aging of 19 cst at 25° C. The cooling liquid had an initial acid value of 0.01 mg KOH/g. The antioxidant of the cooling agent had a half-life of 8 days.

Accordingly, adding an appropriate amount of the triazole-based compound or the diimidazole-based compound could extend the half-life of the antioxidant, thereby greatly extending the lifespan of the dielectric compound. However, too much amounts of triazole-based compound or diimidazole-based compound would cause the cooling liquid to generate precipitation after aging. Too small amounts of triazole-based compound or diimidazole-based compound would shorten the lifespan of the cooling liquid.

### Example 11

100 parts by weight of the dielectric compound in Synthesis Example 1, 0.05 parts by weight of BHT serving as an antioxidant, and 0.001 parts by weight of 3-salicylamido-1,2,4-triazole were mixed to form a cooling liquid. The accelerated aging test of the cooling liquid was performed according to the standard ASTM D1934. The cooling liquid had an initial kinematic viscosity of 19 cst at 25° C., an initial kinematic viscosity of 11 cst at 40° C., and a kinematic viscosity after aging of 19 cst at 25° C. The cooling liquid had an initial acid value of 0.01 mg KOH/g, and an acid value after aging of 0.01 mg KOH/g. The cooling liquid had a thermal decomposition temperature of 203° C. (Td, 5%, measured by TGA) and a flash point of 238° C. (measured according to the standard ASTM D92).

### Comparative Example 8

100 parts by weight of pentaerythritol tetraoctanoate serving as a dielectric compound and 0.2 parts by weight of BHT serving as an antioxidant were mixed to form a cooling liquid. The accelerated aging test of the cooling liquid was performed according to the standard ASTM D1934. The cooling liquid had an initial kinematic viscosity of 29 cst at 25° C., an initial kinematic viscosity of 16 cst at 40° C., and a kinematic viscosity after aging of 29 cst at 25° C. The cooling liquid had an initial acid value of 0.02 mg KOH/g, and an acid value after aging of 0.02 mg KOH/g. The cooling liquid had a thermal decomposition temperature of 206° C. (Td, 5%, measured by TGA) and a flash point of 231° C. (measured according to the standard ASTM D92).

Accordingly, the cooling liquid of the disclosure with a similar flash point could provide a lower viscosity. As such, the cooling liquid of the disclosure had a better property for the cooling system.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. A cooling liquid, comprising:
100 parts by weight of a dielectric compound having a chemical structure of 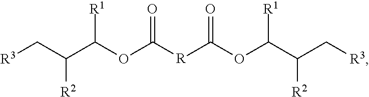
wherein R is C₂₋₁₆ alkylene group,
R¹ is H or C₁₋₃ alkyl group,
R² is H or C₁₋₃ alkyl group, and at least one of R¹ and R² is C₁₋₃ alkyl group, and
R³ is H or C₁₋₇ alkyl group;
0.01 to 0.5 parts by weight of an antioxidant having a chemical structure of 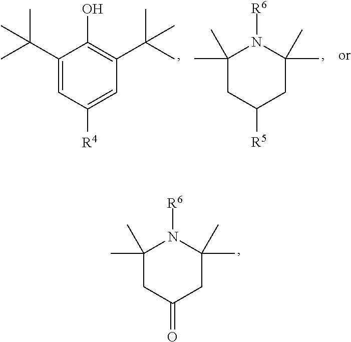
wherein R⁴ is H or C₁₋₁₁ alkyl group; R⁵ is H, C₁₋₆ alkyl group, acrylate group, or methacrylate group; and R⁶ is H or methyl group; and
0.0001 to 0.01 parts by weight of a triazole-based compound or a diimidazole-based compound.

2. The cooling liquid as claimed in claim 1, being free of vegetable oil, animal oil, mineral oil, or a combination thereof.

3. The cooling liquid as claimed in claim 1, wherein the dielectric compound is formed by reacting a C₄₋₁₈ linear diacid and a C₄₋₁₁ branched alcohol.

4. The cooling liquid as claimed in claim 3, wherein the linear diacid is succinic acid, adipic acid, suberic acid, sebacic acid, dodecanedioic acid, tetradecanedioic acid, hexadecanedioic acid, or octadecanedioic acid.

5. The cooling liquid as claimed in claim 3, wherein the branched alcohol is 2-ethyl-1-butanol, isobutyl alcohol, 2-ethylhexanol, 2-ethyloctanol, 2-ethylnonanol, 2-2 methylbutanol, 2-methylhexanol, 2,4-diethylheptanol, 2-heptanol, or 2-nonanol.

6. The cooling liquid as claimed in claim 1, wherein the dielectric compound has a chemical structure of

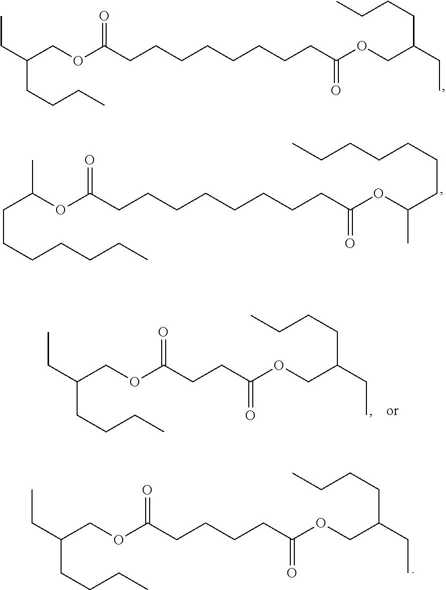 [SMILES: CCCCC(CC)COC(=O)CCCCCCCCC(=O)OCC(CC)CCCC ; CCCCCCCC(C)OC(=O)CCCCCCCCC(=O)OC(C)CCCCCCC ; CCCCC(CC)COC(=O)CCC(=O)OCC(CC)CCCC ; CCCCC(CC)COC(=O)CCCCC(=O)OCC(CC)CCCC]

7. The cooling liquid as claimed in claim 1, wherein the antioxidant is 2,6-di-tert-butyl-p-cresol, 2,6-di-tert-butyl-4-ethylphenol, 2,6-di-tert-butyl-4-sec-2 butylphenol, 2,6-di-tert-butyl-4-butylphenol, 1,2,2,6,6-pentamethyl-4-piperidyl methacrylate, 1,2,2,6,6-pentamethylpiperidine, 2,2,6,6-tetramethylpiperidine, 2,2,6,6-tetramethyl-4-piperidinyl methacrylate, or 2,2,6,6-tetramethylpiperidone.

8. The cooling liquid as claimed in claim 1, wherein the triazole-based compound is 3-salicylamido-1,2,4-triazole, methylbenzotriazole, 5-methylbenzotriazole, 5-carboxybenzotriazole, or 1-hydroxybenzotriazole; wherein the diimidazole-based compound is 2-phenylimidazole, 5-aminobenzimidazole, or 4-(imidazol-1-yl) aniline.

9. A cooling system, comprising:
a container;
the cooling liquid as claimed in claim 1 disposed in the container; and
an electronic device at least partially immersed in the cooling liquid.
